(19) United States
(12) Patent Application Publication
(10) Pub. No.: US 2023/0245933 A1
(43) Pub. Date: Aug. 3, 2023

(54) COMBINING FOCUSED ION BEAM MILLING AND SCANNING ELECTRON MICROSCOPE IMAGING

(71) Applicant: KLA Corporation, Milpitas, CA (US)

(72) Inventors: Youfei JIANG, Milpitas, CA (US); Michael STEIGERWALD, Milpitas, CA (US); Christopher SEARS, Happy Valley, OR (US)

(21) Appl. No.: 17/591,569

(22) Filed: Feb. 2, 2022

(51) Int. Cl. H01L 21/66; H01J 37/31; H01J 37/147; H01L 21/263; B23K 15/00; B23K 15/02; B23K 15/08

(52) U.S. Cl. CPC H01L 22/26; H01J 37/31; H01J 37/1474; H01L 21/2633; B23K 15/0013; B23K 15/002; B23K 15/0006; B23K 15/02; B23K 15/08; B23K 2103/56

(57) ABSTRACT

The dual focused ion beam and scanning electron beam system includes an electron source that generates an electron beam and an ion source that generates an ion beam. The electron beam column directs an electron beam at a normal angle relative to a top surface of the stage. An ion beam column directs the ion beam at the stage. The ion beam is at an angle relative to the electron beam. A detector receives the electron beam reflected from the wafer on the stage.

### FIELD OF THE DISCLOSURE

This disclosure relates to processing semiconductor wafers.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

FIG. 1 illustrates three examples of 3D NAND devices, which are examples of vertical semiconductor devices. 3D NAND devices and other 3D architectures present challenges for defect inspection because of their shape. Electron beams can have difficulty imaging defects deep in a trench. In (a), there are buried defects including a void, a spout, a bridge, and a particle. In (b), a good etched channel is shown on the left, but the channel on the right is tilted. In (c), a good etched channel is shown on the left, but a channel that is not etched through is shown in the center and a channel with residue is shown on the right. Such defects are difficult to detect with standard inspection equipment.

Previously, a focused ion beam (FIB) and a scanning electron microscope (SEM) were used for preparing a thin sample for a transmission electron microscope (TEM). Part of the sample, such as a 3D NAND device or other 3D architecture, is removed by scanning the FIB spot on the sample surface. The milling process can be monitored in real time by collecting secondary electrons signals on an equipped detector, but the image quality is normally not high because of the poor resolution of ion beam and signal collection efficiency. Therefore, the SEM is needed to determine the end point of milling because it can provide better imaging capability. After a lamella is prepared, a micromanipulator transfers the lamella to the TEM holder for further TEM imaging and analysis.

Previously, SEM imaging was typically turned off when conducting FIB sputtering because the magnetic field from the objective lens of the SEM column deflected the ion beam by a few hundreds of micrometers. The process of turning on and off the objective lens of the SEM column is relatively long because of the settling and hysteresis of magnetic materials. To reduce the process time by keeping the objective lens of SEM column turned on, the deflection of the ion beam is compensated by deflectors inside the FIB column so that the ion beam can coincident with electron beam at the sample. However, the deflection compensation still introduces some off-axis aberrations to cause an ion beam spot size increase and shape deformation. In addition, the scanning of ion beam to sputter materials also is a slow process because the scanning bandwidth can be limited by the scanning voltage, which depends on the desired field of view (FOV). Furthermore, the equipped SEM was only used for providing high-resolution images without a capability to review and inspect semiconductor defects.

Therefore, improved systems and techniques are needed.

### BRIEF SUMMARY OF THE DISCLOSURE

A system is provided in a first embodiment. The system includes a stage configured to hold a wafer; an electron source that generates an electron beam; a scanning electron beam column coupled to the electron source; a detector configured to receive the electron beam reflected from the wafer on the stage; an ion source that generates an ion beam; and an ion beam column coupled to the ion source. The scanning electron beam column directs the electron beam at the stage. The electron beam is directed at a normal angle relative to a top surface of the stage. The ion beam column directs the ion beam at the stage. The ion beam column direct the ion beam at an angle relative to the electron beam.

The scanning electron beam column can include a gun lens, an aperture, a condense lens, at least two deflectors, and an objective lens. In an instance, the objective lens is disposed in a path of the electron beam between the stage and the electron source. The at least two deflectors are disposed in the path of the electron beam between the objective lens and the electron source. The condense lens is disposed in the path of the electron beam between the at least two deflectors and the electron source. The aperture is disposed in the path of the electron beam between the condense lens and the electron source. The gun lens is disposed in the path of the electron beam between the aperture and the electron source.

The ion beam column can include a condense lens, a deflector, an aperture, a beam bender, and an objective lens. In an instance, the objective lens is disposed in a path of the ion beam between the stage and the ion source. The beam bender is disposed in the path of the ion beam between the objective lens and the ion source. The aperture is disposed in the path of the ion beam between the beam bender and the ion source. The deflector is disposed in the path of the ion beam between the aperture and the ion source. The condense lens is disposed in the path of the ion beam between the deflector and the ion source.

The ion beam column can be configured to bend the ion beam in the ion beam column.

The ion beam column can be electrostatic.

The system can further include a xenon source in fluid communication with the ion source.

The ion beam column can provide a Gaussian beam mode and/or a projection beam mode.

The angle can be from 50° to 60°. For example, the angle can be 60°.

The system can further include a second ion source that generates a second ion beam and a second ion beam column coupled to the second ion source. The second ion beam column can direct the second ion beam at the stage. The second ion beam column can direct the second ion beam at a 90° azimuthal angle with respect to the ion beam.

The system can further include a processor configured to control blanking of the ion beam and the electron beam.

A method is provided in a second embodiment. The method includes directing an ion beam at a wafer on a stage whereby the ion beam mills the wafer. The ion beam is directed through an ion beam column. The ion beam is blanked such that the ion beam does not reach the wafer. An electron beam is directed at the wafer during the blanking. The electron beam is directed through an electron beam column. The ion beam column directs the ion beam at an angle relative to the electron beam. The electron beam is directed at a normal angle relative to a top surface of the wafer. Using a processor, a depth that the ion beam milled the wafer can be determined using the electron beam.

The ion beam can include xenon ions.

The ion beam can be bent in the ion beam column.

The angle can be from 50° to 60°. For example, the angle can be 60°.

The method can further include detecting a signal of the electron beam reflected from the wafer to image the wafer and performing defect inspection of the wafer using a processor.

The method can further include directing a second ion beam at the wafer on the stage. The second ion beam is directed at a 90° azimuthal angle with respect to the ion beam.

### DESCRIPTION OF THE DRAWINGS

For a fuller understanding of the nature and objects of the disclosure, reference should be made to the following detailed description taken in conjunction with the accompanying drawings, in which:

FIG. 1 illustrates three examples of 3D NAND devices and defects;

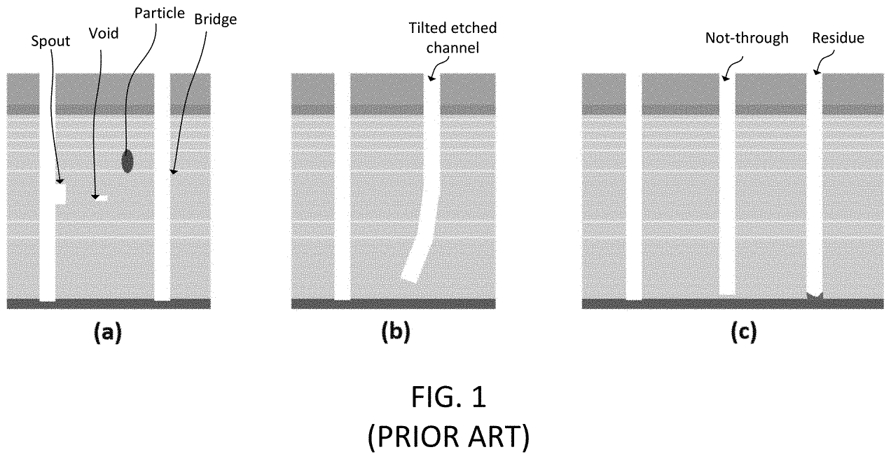

FIG. 2 is a schematic of the FIB optics in accordance with the present disclosure;

FIG. 3 is a schematic of the SEM optics in accordance with the present disclosure;

FIG. 4 is a chart comparing relative sputtering rate and incident angle using xenon for various materials used in semiconductor devices;

FIG. 5 illustrates a block diagram of a system to synchronize blanking;

FIG. 6 illustrates an embodiment of synchronization of the ion beam and electron beam;

FIG. 7 illustrates an embodiment of Gaussian beam mode;

FIG. 8 illustrates a resulting beam profile for the Gaussian beam mode of FIG. 7;

FIG. 9 illustrates an embodiment of projection beam mode;

FIG. 10 illustrates a resulting beam profile for the projection beam mode of FIG. 9;

FIG. 11 illustrates exemplary beam profiles showing dispersion along the bending direction caused by the beam bender because of energy spread in the ion beam;

FIG. 12 illustrates a delayer and view operation mode;

FIG. 13 illustrates a slice and image operation mode;

FIG. 14 illustrates an embodiment of a system that includes a second ion beam; and

FIG. 15 is a flowchart of a method in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments disclosed herein combine a FIB for fast milling and an SEM for fast imaging. This system can be used for delayering the materials and then reviewing and/or inspecting defects in a semiconductor wafer. These defects can include those that are deeply buried or on the bottoms of high aspect ratio (HAR) trenches or holes. The system can compete with other FIB tools for preparing TEM samples and performing failure analysis of semiconductor device because it has high throughput.

The FIB can use a high beam current. The FIB is used for sputtering, so the resolution is less of a concern than that of the beam used for imaging. The objective lens in the SEM optics may not deflect the ion beam. The SEM objective lens may only have a magnetic field without an electrostatic field between the objective lens and the wafer. The magnetic field may cause a small deflection field for a heavy ion beam, but this can be compensated for using an upper deflector inside the ion column.

A beam bender can be used to bend the ion beam from one tilting angle to a final incident angle. The beam bender also can operate as a blanker.

The FIB can be switched between a Gaussian beam and a project beam by changing the strength of the column's objective lens. The projection beam mode may be used during operation due to its benefits.

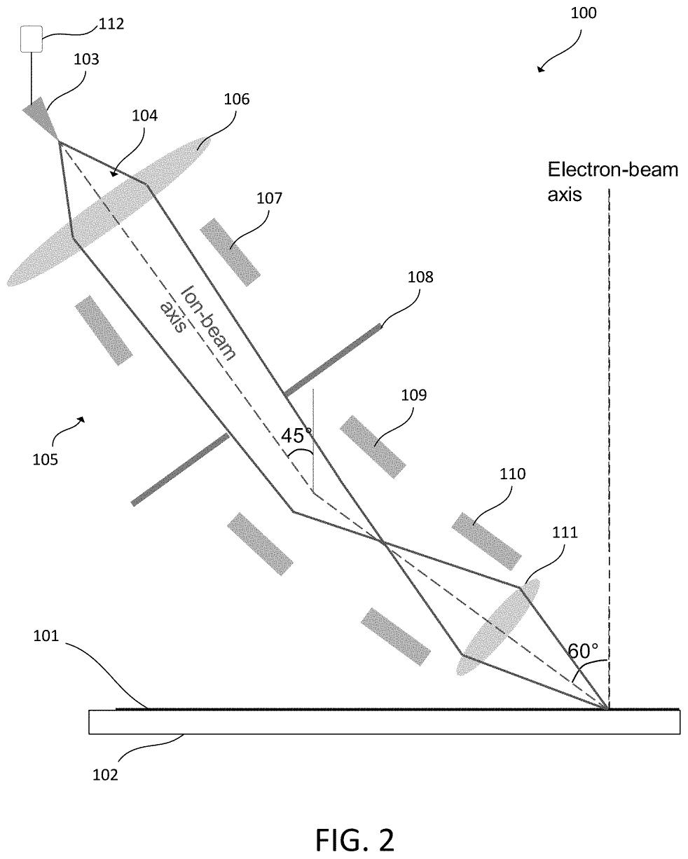

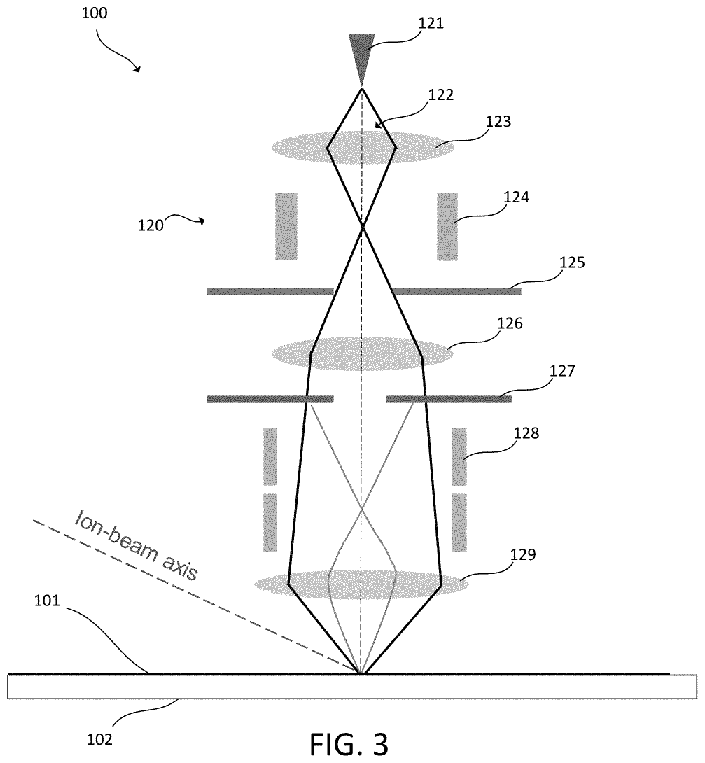

FIG. 2 is a schematic of the FIB optics and FIG. 3 is a schematic of the SEM optics in a system 100. The system 100 includes a vertical SEM column and a tilted FIB column. This dual beam tool can operate as a semiconductor defects review and/or inspection tool. Compared to preparing a TEM lamella for a deep defect, the embodiments disclosed herein can improve throughput by more than 100 times.

The system 100 includes a stage 102 configured to a hold a wafer 101. An ion source 103 generates an ion beam 104. The ion source 103 can include a plasma source with an accelerator. An ion beam column 105 is coupled to the ion source 103. The ion beam column 105 is configured to direct the ion beam 104 at the stage 102. As shown in FIG. 2, the ion beam 104 is directed at the stage 102 at an angle relative to the electron beam axis (which is shown in more detail in FIG. 3). The electron beam axis can be normal relative to a top surface of the stage 102 or wafer 101. The ion beam 104 is directed neither parallel nor perpendicular to the electron beam axis.

The tilted ion beam column 105 can have a similar optical architecture to that of the of the electron beam. The ion beam column 105 includes a condense lens 106, first deflector 107, aperture 108, beam bender 109, second deflector 110, and objective lens 111. The ion beam column 105 is coupled to the ion source 103 and may include fewer deflectors than the corresponding electron beam column. The ion beam column 105 instead includes a beam bender 109 and may include one or more deflectors upstream of the objective lens 111. The ion beam 104 can leave the ion source 103 and pass through the condense lens 106 and first deflector 107 before reaching the aperture 108. Downstream of the aperture 108, the ion beam 104 passes through the beam bender 109, deflector 110, and objective lens 111 before reaching the wafer 101. As shown in FIG. 2, the ion beam column 105, which can be electrostatic, can bend the ion beam 104. Thus, the condense lens 106, first deflector 107, beam bender 109, second deflector 110, and/or objective lens 111 can be electrostatic.

The ion beam source 103 can emit an ion species, such as xenon. Xenon is heavy and inert. The ion beam source 103 can be connected to a source 112, which can contain xenon or other species such as argon or gallium. The ions are emitted from the ion source 103 into the ion beam 104. The ion beam current in the system 100 is typically larger than 100 nA for improved throughput. For example, the ion beam current may be from 100 nA to 1 μA. The ion beam energy may be from 10 keV to 20 keV. The ion beam 104 resolution may be less important than throughput for certain applications.

The condense lens 106 is disposed in the path of the ion beam 104 between the first deflector 107 and the ion source 103. The condense lens 106 can focus the ion beam 104. In an instance, the condense lens 106 is an Einzel lens.

The first deflector 107 is disposed in the path of the ion beam 104 between the aperture 108 and the ion source 103. The first deflector 107 deflects or otherwise adjusts the path of the ion beam 104. The aperture 108 is disposed in the path of the ion beam 104 between the beam bender 109 and the ion source 103. The aperture 108 is coupled in operation with the first deflector 107.

The beam bender 109 is disposed in the path of the ion beam 104 between the objective lens 111 and the ion source 103. In an instance, the beam bender 109 bends the axis of the ion beam 104 from 45° from a normal angle off the stage 102 or wafer 101 surface to 60° from the normal angle off the stage 102 or wafer 101 surface.

The beam bender 109 also can be a blanker. This blanker function can prevent the ion beam 104 from impacting the wafer 102. In an instance, the ion beam is directed to a Faraday cup during blanking so ion beam stability can be monitored.

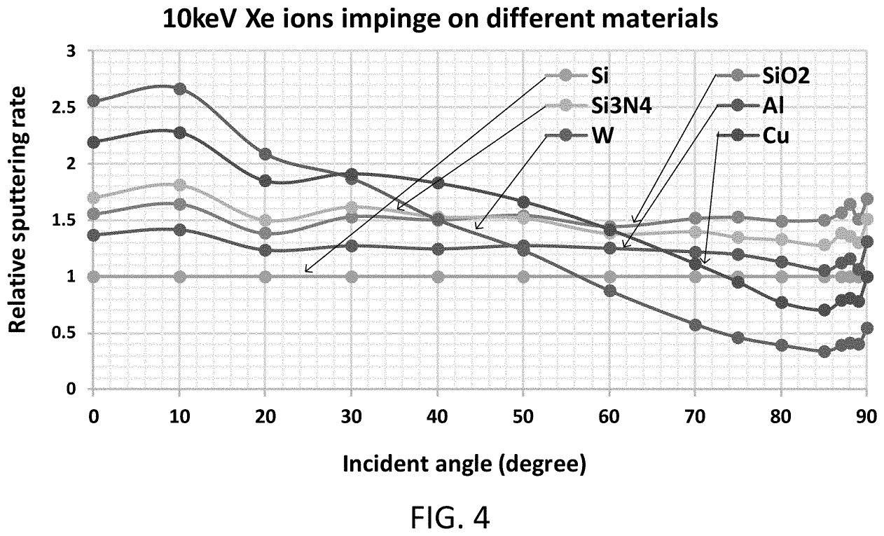

The angle of the ion beam 104 can be from 50° to 60° relative to a normal angle off the stage 102 or wafer 101 surface, though other angles are possible. Simulations indicate that for an approximately 60° incident angle for ion beam 104, the smallest variation of xenon ion sputtering rates for six common materials in the semiconductor industry will occur. The effect of incident angle is shown in FIG. 4. Different ion species may have a different optimal incident angle than that of xenon.

In an instance, the angle of the ion beam column 105 is fixed. With this design, the angle of the ion beam is changed by adjusting electrostatic components of the ion beam column. However, the axis of the ion beam column 105 itself is not changed and the components inside the ion beam column 105 do not move. The ion beam column 105 deflects the ion beam to adjust the incident angle instead of translating components in the ion beam column 105 relative to each other or relative to components outside the ion beam column 105.

Turning back to FIG. 2, the second deflector 110 is disposed in the path of the ion beam 104 between the objective lens 111 and the beam bender 109. The second deflector 110 can scan the beam.

The objective lens 111 is disposed in the path of the ion beam 104 between the stage 102 and the ion source 103. The objective lens 111 can provide resolution of the ion beam 104.

FIG. 3 illustrates the scanning electron beam column 120. The ion beam axis of the ion beam 104 from FIG. 2 is illustrated in FIG. 3. The electron beam column 120 is coupled to an electron source 121 that generates an electron beam 122. The electron source 121 can be a Schottky electron source, cold field emission electron source, thermal field emission electron source, thermal emission electron source, or other devices that emit electrons. The electron beam column 120 directs the electron beam 122 at the wafer 101 on the stage 102. The electron beam 122 and the ion beam 104 can be directed to the same point on the wafer 101.

In an instance, the scanning electron beam column 120 includes a gun lens 123, a first deflector 124, an aperture 125, a condense lens 126, a detector 127, a second deflector 128 (which can include one, two, or more sets of deflectors), and an objective lens 129. The detector 127 is configured to receive the electron beam reflected from the wafer 101 on the stage 102 and collect the resulting signals. The electron beam 122 can leave the electron source 121 and pass through the gun lens 123 and the first deflector 124 before reaching the aperture 125. Downstream of the aperture 125, the electron beam 122 passes through the condense lens 126, the detector 127, the second deflector 128, and the objective lens 129. Some or all of the electron beam 122 is reflected from the surface of the wafer 101 and passes through the objective lens 129 and second deflector 128 before reaching the detector 127. Signals from the detector 127 can be used to determine a depth of the milling or can be used for defect inspection.

The objective lens 129 is disposed in a path of the electron beam 122 between the stage 102 and the electron source 121. The objective lens 129 can provide resolution of the electron beam 122, which can affect collection efficiency.

The second deflector 128 (which may be at least two deflectors) is disposed in the path of the electron beam 122 between the objective lens 129 and the electron source 121. The second deflector 128 can be used for scanning the electron beam 122 to the FOV.

The condense lens 126 is disposed in the path of the electron beam 122 between the second deflector 128 and the electron source 121. The condense lens 126 can focus the electron beam 122.

The detector 127 is disposed in the path of the electron beam 122 between the second deflector 128 and the condense lens 126. The detector 127 can be configured for specific applications. For review application, the detector 127 can be designed to enhance topographic information of defects. The detector 127 may be or include one or more energy-dispersive X-ray spectroscopy (EDX) detectors for defect review purpose. For inspection applications, the detector 127 can be designed to separate the physical space of electrons for detecting special defects, such as shallow-buried defects, HAR defects, voltage contrast (VC) defects, or physical defects.

The aperture 125 is disposed in the path of the electron beam 122 between the condense lens 126 and the electron source 121. The aperture 125 can be motorized.

The gun lens 123 is disposed in the path of the electron beam 122 between the aperture 125 and the electron source 121.

The first deflector 124 is disposed in the path of the electron beam 122 between the gun lens 123 and the aperture 125. The first deflector 124 can align the electron beam 122 or blank the electron beam 122. The electron beam 122 can be blanked to an aperture (e.g., aperture 125), though other blanking options are possible.

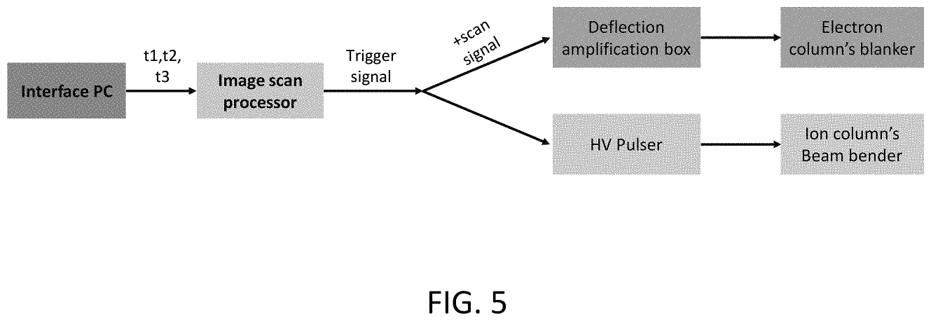

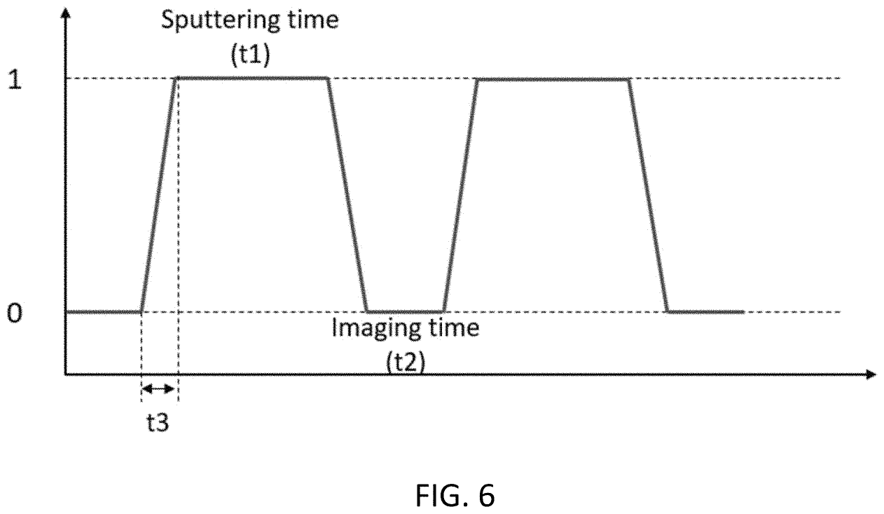

During operation, the system 100 can activate both SEM and FIB columns. The ion source 103, ion beam column 105, electron source 121, and electron beam column 120 can be activated. First, the electron beam column 120 can be used to image the wafer 101. In an instance, the ion beam can be blanked during this imaging. In another instance, the ion source 103 and ion beam column 105 can be activated after this imaging. The stage 102 can be moved to the desired position using actuators. Then the electron beam column 120 blanks the electron beam 122 so that the ion beam 104 in the ion beam column 105 can be directed at the wafer 101 to begin milling the wafer 101. When the selected area of wafer 101 is milled to a desired depth, the ion beam 104 is blanked again (e.g., using the beam bender 109) so that the ion beam 104 does not impact the wafer 101. The electron beam 122 is then directed at the wafer 101 to image the milled area. In an instance, the electron beam 122 is not blanked so that the electron beam 122 impacts the wafer 101. The synchronization of ion beam milling and electron beam imaging is shown in FIGS. 5 and 6. In FIGS. 5 and 6, t1 is the sputtering time (i.e., milling), t2 is the imaging time, and t3 is the interval between t1 and t2. Switching between imaging and milling modes can be performed by changing a strength of the objective lens in the electron beam column.

The processor (e.g., the interface PC and/or image scan processor) can be used to control blanking of the ion beam and/or electron beam. The processor can determine t1, t2, and t3 for operation. The processor also can be used to determine a depth of any milling, which can be related to t1. The processor is coupled to components in the system 100. The processor typically comprises a programmable processor, which is programmed in software and/or firmware to carry out the functions that are described herein, along with suitable digital and/or analog interfaces for connection to the other elements of the system 100. Alternatively or additionally, the processor comprises hard-wired and/or programmable hardware logic circuits, which carry out at least some of the functions of the processor. Although the processor is shown in FIG. 5, for the sake of simplicity, as monolithic functional blocks, in practice the processor may comprise multiple, interconnected control units, with suitable interfaces for receiving and outputting the signals that are illustrated in the figures and are described in the text. Program code or instructions for the processor to implement various methods and functions disclosed herein may be stored in readable storage media, such as a memory in the interface PC or other memory.

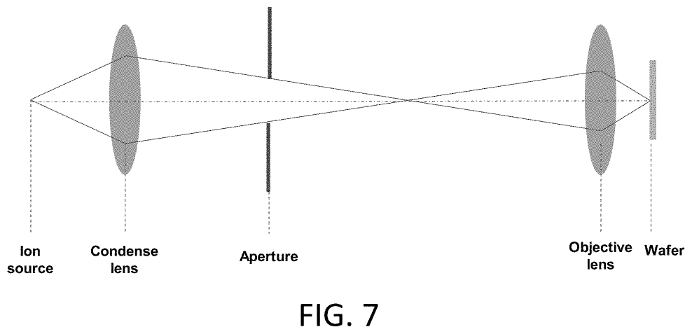

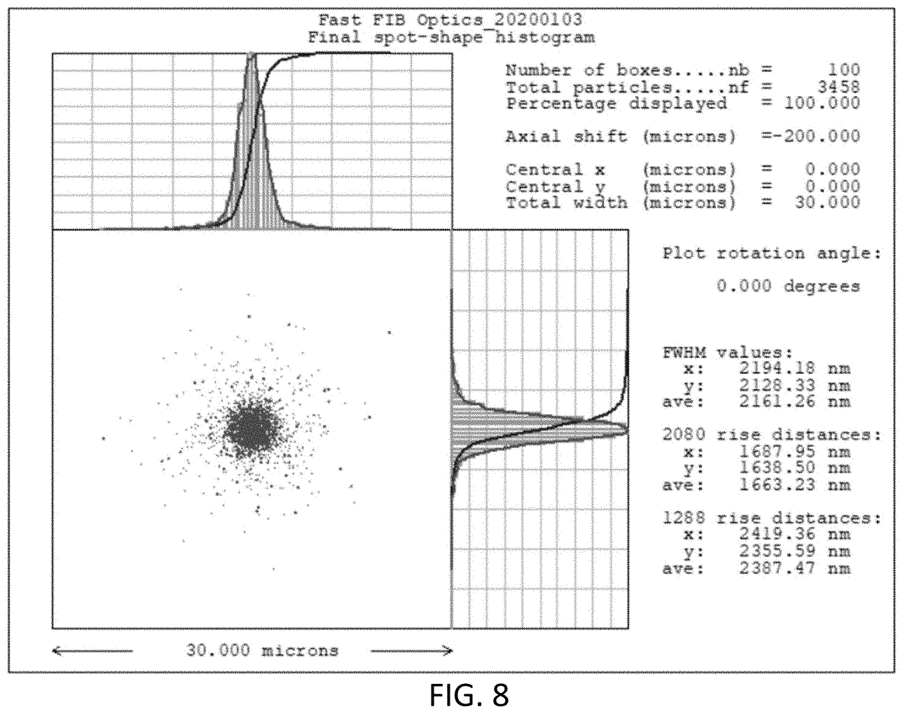

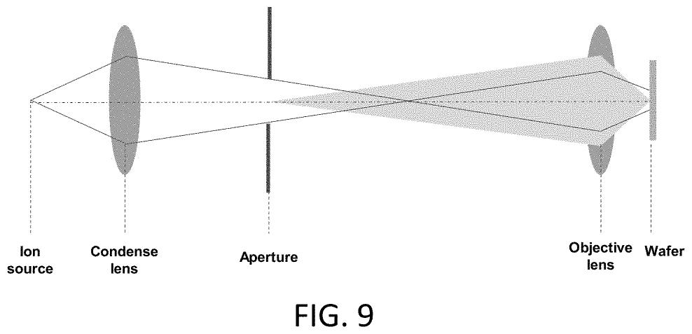

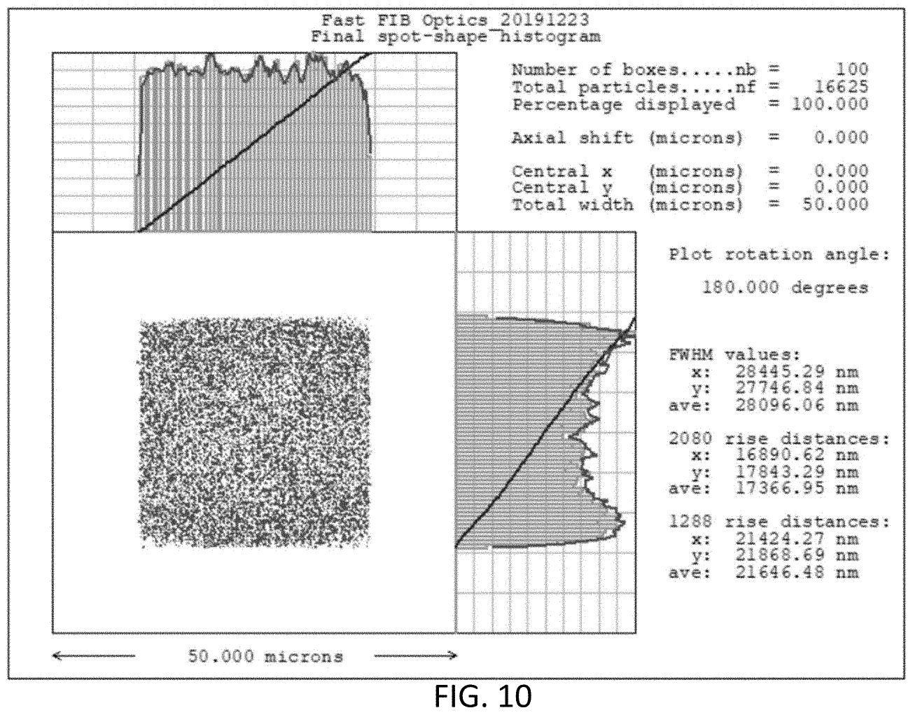

The focused ion beam typically has two modes: Gaussian beam and projection beam modes. These modes are shown in FIGS. 7-10. For the Gaussian beam mode in FIG. 7, the object plane of objective lens is the image plane of condense lens. For the projection beam mode in FIG. 9, the object plane of objective lens is the aperture plane. To mill a selected area, scanning may be used for Gaussian beam mode. Scanning may be avoided with projection beam mode. Imaging during ion beam milling process may not be needed so the projection beam mode may be used to avoid scanning. The projection mode has increased throughput and can be insensitive to lens aberrations. However, the Gaussian mode may be preferred for certain applications.

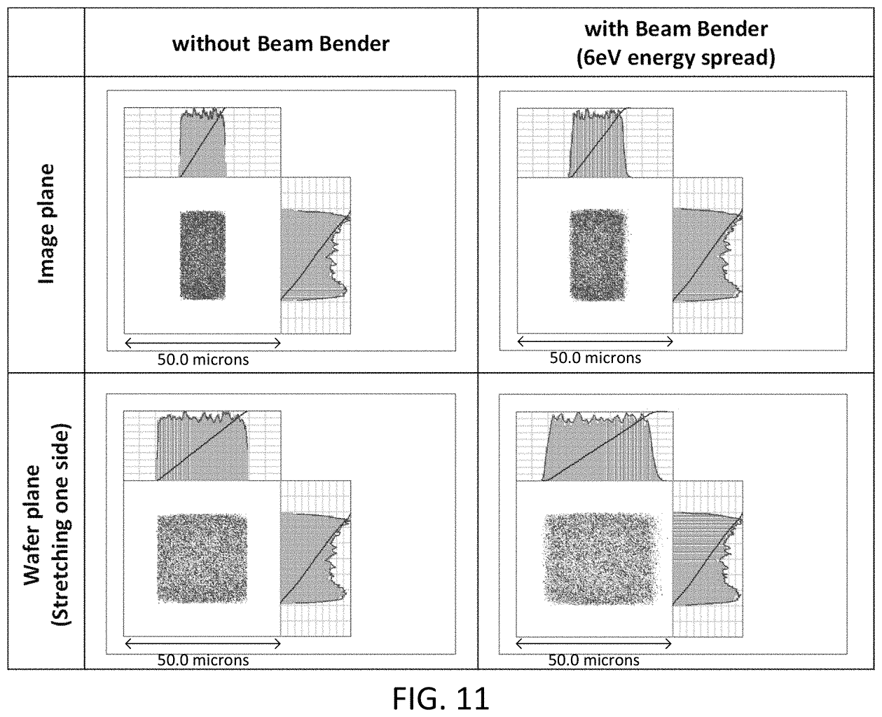

If the ion beam is tilted at approximately 60° as illustrated in FIG. 2, the stretching effect of ion beam spot on the wafer can be affected. The beam width can be doubled along the incident plane, while a perpendicular width can remain the same. Therefore, if a square projected ion beam spot on the wafer is desired, then an oblong aperture hole can be used as shown in FIG. 11.

The beam bender 109 can operate as a blanker and, in an example, can bend the ion beam 104 from 45° in the upper section of the ion beam column 105 to 60° in the lower section of the ion beam column 105. 60° tilting in the upper section of the ion beam column 105 may mechanically interference with the main chamber housing. However, the beam bender can introduce dispersion on the beam spot due to the energy spread of ion beam. As shown in FIG. 11, this dispersion on the ion beam spot does not degrade the central area uniformity.

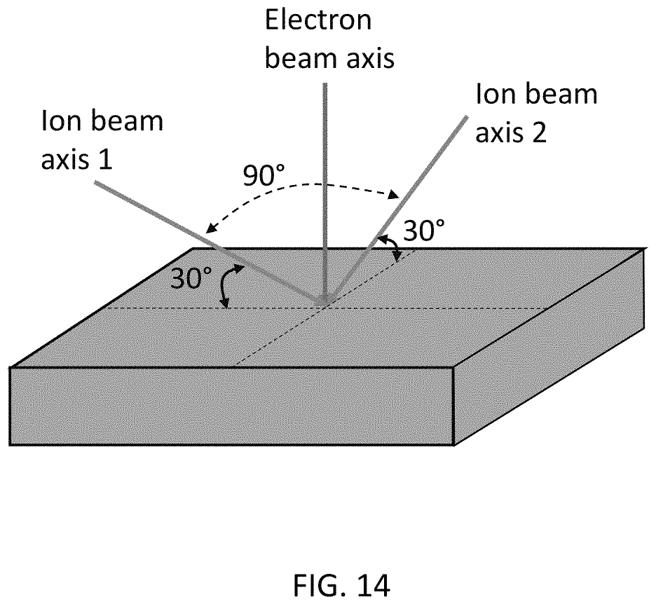

Multiple ion beams can be used, as shown in FIG. 14. In an embodiment, the system has two ion beam columns with one electron beam column. The second ion beam column has 90-degree azimuthal angle with respect to the first ion beam column. The incident angle of the second ion beam may be the same as that of the first ion beam, which is 60-degree with respect to the wafer normal (i.e., the electron beam axis). Two cross ion beam columns can provide two sputtering orientations, which may be helpful for achieve better flatness of milled area. The second ion beam column may have different ion species and smaller beam current for fine milling. The second ion beam column may be similar to that illustrated in FIG. 2.

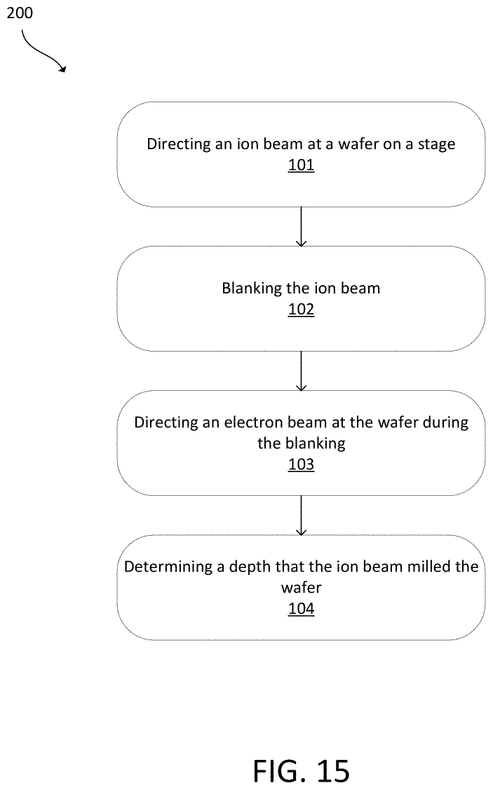

FIG. 15 is a flowchart of a method 200. At 201, an ion beam is directed at a wafer on a stage whereby the ion beam mills the wafer. The ion beam can be xenon ions or other species. The ion beam is directed through an ion beam column. For example, the ion beam can be directed through the ion beam column 105 of system 100. As shown in FIG. 2, the ion beam can be bent in the ion beam column.

At 102, the ion beam is blanked such that the ion beam does not reach the wafer. Then, at 103, an electron beam is directed at the wafer during the blanking. The electron beam is directed through an electron beam column, such as the electron beam column 120 of system 100. The ion beam column directs the ion beam at an angle relative to the electron beam. The angle can be from 50° to 60° (e.g., 60°). The electron beam can be directed at a normal angle relative to a top surface of the wafer on the stage.

At 104, a depth that the ion beam milled the wafer using the electron beam is determined using a processor. The processor also can image the wafer for defect inspection.

In an instance, a second ion beam can be directed at the wafer on the stage. The second ion beam can be directed at a 90° azimuthal angle with respect to the ion beam.

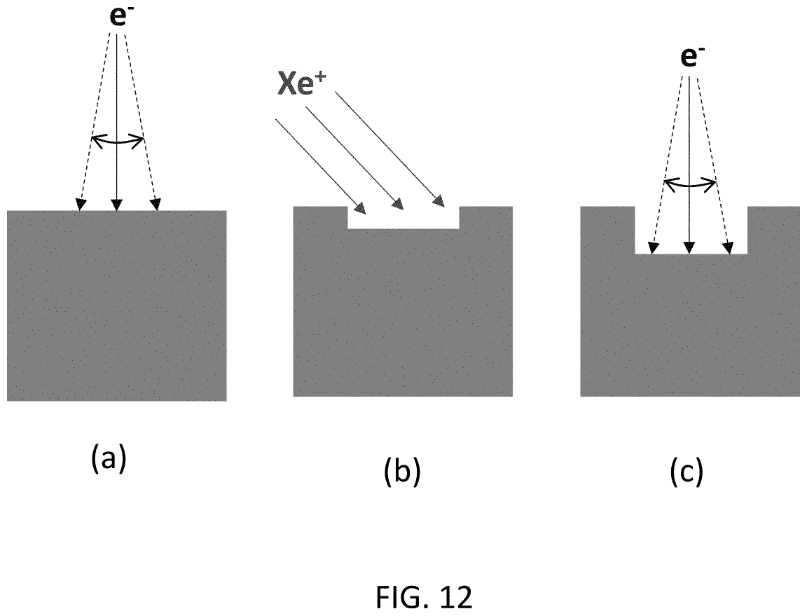

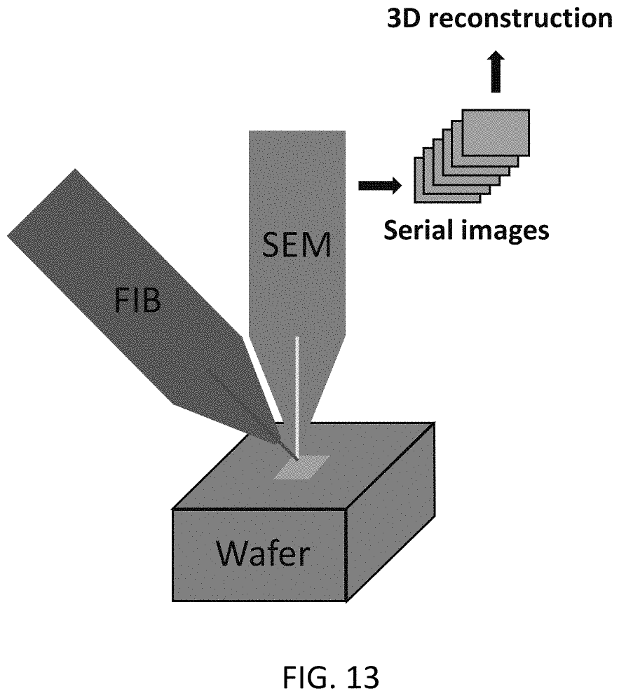

Various operation modes are possible. Two operation modes are shown in FIGS. 12 and 13. In FIG. 12, a delayer and view mode is illustrated. SEM imaging is performed before milling at (a). At (b), the area of interest is milled to a desired depth (e.g., a few hundreds of nanometers to tens of micrometers). At (c), the SEM imaging is performed to review or inspect the defects. The end point of milling can be above the defects to avoid damage to these defects.

In FIG. 13, a slice and image mode is illustrated. The area of interest is sputtered for a small depth (e.g., a few nanometers to tens of nanometers). Then a SEM image is captured. The sputtering and imaging processes can be repeated multiple times until reaching the desired depth. A series of SEM images is post-processed to reconstruct 3D volume of the sample.

While SEM imaging can be performed before the milling, a separate optical inspection tool can be used instead to sample the wafer and potentially find a hot spot.

The method 200, which can use the system 100 or other embodiments disclosed herein, provides high throughput. Fast milling results from, for example, heavy ion species, large beam current, projected beam mode, and/or large incident angle. Fast SEM imaging can be performed using fast detection chain and electronics. The objective lens of SEM column remains on when switching from imaging to milling because the ion beam deflection caused by this magnetic field is within tolerable range. Even using one deflector to compensate this ion beam deflection, the resultant aberrations changing the uniformity of projected ion beam spot are still typically acceptable.

The SEM is capable of reviewing and/or inspecting semiconductor defects in advanced or next generation semiconductor devices. For example, the system can detect the extremely HAR defects (e.g. HAR >100:1), which are currently not detectable by available techniques. For extremely HAR defects, the system can use the FIB to mill away a depth of trenches or holes (i.e., reduce HAR from 100:1 to <50:1). Then the SEM column can detect the defects.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a stage configured to hold a wafer;
an electron source that generates an electron beam;
a scanning electron beam column coupled to the electron source, wherein the scanning electron beam column directs the electron beam at the stage, and wherein the electron beam is directed at a normal angle relative to a top surface of the stage;
a detector configured to receive the electron beam reflected from the wafer on the stage;
an ion source that generates an ion beam; and
an ion beam column coupled to the ion source, wherein the ion beam column directs the ion beam at the stage, and wherein the ion beam column direct the ion beam at an angle relative to the electron beam.

2. The system of claim 1, wherein the scanning electron beam column includes a gun lens, an aperture, a condense lens, at least two deflectors, and an objective lens.

3. The system of claim 2, wherein the objective lens is disposed in a path of the electron beam between the stage and the electron source, wherein the at least two deflectors are disposed in the path of the electron beam between the objective lens and the electron source, wherein the condense lens is disposed in the path of the electron beam between the at least two deflectors and the electron source, wherein the aperture is disposed in the path of the electron beam between the condense lens and the electron source, and wherein the gun lens is disposed in the path of the electron beam between the aperture and the electron source.

4. The system of claim 1, wherein the ion beam column includes a condense lens, a deflector, an aperture, a beam bender, and an objective lens.

5. The system of claim 4, wherein the objective lens is disposed in a path of the ion beam between the stage and the ion source, wherein the beam bender is disposed in the path of the ion beam between the objective lens and the ion source, wherein the aperture is disposed in the path of the ion beam between the beam bender and the ion source, wherein the deflector is disposed in the path of the ion beam between the aperture and the ion source, and wherein the condense lens is disposed in the path of the ion beam between the deflector and the ion source.

6. The system of claim 1, wherein the ion beam column is configured to bend the ion beam in the ion beam column.

7. The system of claim 1, wherein the ion beam column is electrostatic.

8. The system of claim 1, further comprising a xenon source in fluid communication with the ion source.

9. The system of claim 1, wherein the ion beam column provides a Gaussian beam mode and a projection beam mode.

10. The system of claim 1, wherein the angle is from 50° to 60°.

11. The system of claim 10, wherein the angle is 60°.

12. The system of claim 1, further comprising:
a second ion source that generates a second ion beam; and
a second ion beam column coupled to the second ion source, wherein the second ion beam column directs the second ion beam at the stage, and wherein the second ion beam column direct the second ion beam at a 90° azimuthal angle with respect to the ion beam.

13. The system of claim 1, further comprising a processor configured to control blanking of the ion beam and the electron beam.

14. A method comprising:
directing an ion beam at a wafer on a stage whereby the ion beam mills the wafer, wherein the ion beam is directed through an ion beam column;
blanking the ion beam such that the ion beam does not reach the wafer;
directing an electron beam at the wafer during the blanking, wherein the electron beam is directed through an electron beam column, wherein the ion beam column directs the ion beam at an angle relative to the electron beam, and wherein the electron beam is directed at a normal angle relative to a top surface of the wafer; and
determining, using a processor, a depth that the ion beam milled the wafer using the electron beam.

15. The method of claim 14, wherein the ion beam includes xenon ions.

16. The method of claim 14, wherein the ion beam is bent in the ion beam column.

17. The method of claim 14, wherein the angle is from 50° to 60°.

18. The method of claim 17, wherein the angle is 60°.

19. The method of claim 14, further comprising detecting a signal of the electron beam reflected from the wafer to image the wafer and performing defect inspection of the wafer using a processor.

20. The method of claim 14, further comprising directing a second ion beam at the wafer on the stage, wherein the second ion beam is directed at a 90° azimuthal angle with respect to the ion beam.
